(19) United States
(12) Patent Application Publication
(10) Pub. No.: US 2013/0075977 A1
(43) Pub. Date: Mar. 28, 2013

(54) PISTON RING FOR ENGINE AND MANUFACTURING METHOD THEREOF

(71) Applicant: Jeong Uk An, Seoul (KR)

(72) Inventor: Jeong Uk An, Seoul (KR)

(73) Assignee: HYUNDAI MOTOR COMPANY, Seoul (KR)

(21) Appl. No.: 13/323,564

(22) Filed: Dec. 12, 2011

(30) Foreign Application Priority Data
Sep. 27, 2011 (KR) 10-2011-0097315

(51) Int. Cl. F16J 9/00; C23C 16/44; C23C 16/27

(52) U.S. Cl. 277/434; 427/249.7

(57) ABSTRACT

Disclosed is a piston ring for an engine and a method of manufacturing the piston ring. The piston ring includes at least a Cr (Chromium) coating layer coated on a surface of a base material, and a Si-DLC (Silicon doped Diamond Like Carbon) coating layer coated on an outermost layer above the Cr layer and the base material. More specifically, the Si-DLC layer includes about 3 to 10 wt. % of Si.

### CROSS-REFERENCE TO RELATED APPLICATION

This application claims under 35 U.S.C. §119(a) the benefit of Korean Patent Application No. 10-2011-0097315 filed on Sep. 27, 2011, the entire contents of which are incorporated herein by reference.

### BACKGROUND

(a) Technical Field

The present disclosure relates to a piston ring for an engine configured so that an outer circumference of the piston ring is treated with low friction Si-DLC (Silicon doped Diamond Like Carbon) to reduce friction loss in an engine cylinder and to improve fuel efficiency, and a method of manufacturing the piston ring thereof.

(b) Background Art

A piston ring is defined as one pair of rings that are fitted into grooves of an outer circumference of a piston to maintain a certain degree of air-tightness between the piston and an inner wall of a cylinder and scrape a lubricant off the wall of the cylinder, thus preventing the lubricant from flowing into a combustion chamber.

FIG. 1 shows a coating state of a conventional piston ring for an engine. Such a piston ring has difficulties in maintaining durability as well as having a low frictional coefficient. To this end, the outer circumference of a piston ring 10 is generally plated with Cr (Chromium) or nitride (gas nitriding). In recent years, various surface treatment technologies using CrN (Chromium Nitride) or the like have been proposed to reduce friction loss and improve durability because of high oil prices and restrictions on CO₂.

Among the surface treatment methods, DLC (Diamond Like Carbon) is an intermediate phase between diamond and graphite, so that the DLC retains a low frictional coefficient of the graphite, a high degree of hardness of the diamond, and a superior chemical resistance. Therefore, when the DLC is applied to the outer circumference of the piston ring, the friction loss of the engine can be further reduced, thus resulting in improvement in the fuel efficiency of a vehicle.

However, the DLC is problematic in that friction and durability are deteriorated when the DLC is exposed at a high temperature for a lengthy period of time, so that residual stress in the coating increases. As the stress on the coating increases, the thickness of the coating also may increase in certain portions. When this happens, the coating may be stripped due to the increased friction.

The foregoing is designed merely to aid in the understanding of the background of the present invention.

### SUMMARY OF THE DISCLOSURE

The present invention has been made in an effort to solve the above-described problems associated with prior art. An object of the present invention is to provide a piston ring for an engine configured so that an outer circumference of the piston ring is coated with low friction Si-DLC to reduce friction loss in an engine cylinder and to improve fuel efficiency, thus simultaneously achieving low friction characteristics and high durability, and a method of manufacturing the piston ring.

In one aspect, the present invention provides a piston ring for an engine including a chromium (Cr) coating layer coated on a surface of a base material; and an Silicon doped Diamond Like Carbon (Si-DLC) coating layer coated on an outermost layer of on top of the Cr layer and the base material, and comprising about 3 to 10 wt. % of Si. Preferably, the piston ring may further include a Chromium Nitride (CrN) coating layer coated between the Cr coating layer and the Si-DLC coating layer.

In some embodiments, the Si-DLC coating layer may have a thickness of about 0.1 to 10 μm, and the Si may be uniformly distributed in the Si-DLC coating layer. The Si content of the Si-DLC coating layer may be increased in a direction from an inner portion to an outer portion of the coating layer.

The Si-DLC coating layer may be formed by chemical reaction between carbonization gas (CₓH_{y}) and TMS (Tetra-methylsilane, Si(CH₃)₄) gas or between carbonization gas and HMDSO (Hexamethyldisiloxane, O(Si(CH₃)₃)₂) gas.

The Cr coating layer and the Si-DLC coating layer may be formed on only an outer circumference of the base material making contact with an inner wall of a cylinder.

In another aspect, the present invention provides a method of manufacturing a piston ring for an engine including a) coating a Cr coating layer on a base material; and b) coating a Si-DLC coating layer through chemical reaction between carbonization gas (CₓH_{y}) and TMS gas or between carbonization gas and HMDSO gas.

Preferably, the method may further include coating a CrN coating layer through chemical reaction between N₂ gas and sputtered Cr ions, while coating a Cr coating layer on the base material. Additionally, while coating a Si-DLC coating layer, an injection quantity of the TMS or the HMDSO gas may be adjusted so that Si content of the Si-DLC coating layer is increased from a inner portion to an outer portion of the coating layer. More specifically, the Si-DLC coating layer may comprise 3 to 10 wt. % of Si.

As apparent from the above description, the present invention provides a piston ring for an engine and a manufacturing method thereof, in which the frictional coefficient of Si-DLC is less than Cr plating and nitriding by at least 23%, and is less than CrN by at least 11%, thus reducing the friction loss of the piston ring and improving fuel efficiency by at least 0.2 to 0.5%. Other aspects and preferred embodiments of the invention are discussed infra.

### BRIEF DESCRIPTION OF THE DRAWINGS

The above and other features of the present invention will now be described in detail with reference to certain exemplary embodiments thereof illustrated in the accompanying drawings which are given hereinbelow by way of illustration only, and thus are not limitative of the present invention, and wherein:

FIG. 1 is a view showing a coating state of a conventional piston ring for an engine;

FIG. 2 is a view showing a piston ring for an engine in accordance with an embodiment of the present invention;

FIG. 3 is a sectional view showing a coating of the piston ring for the engine shown in FIG. 2;

FIG. 4 is a view showing an apparatus for manufacturing the piston ring for the engine shown in FIG. 2; and

FIGS. 5 to 7 are graphs showing the comparison of performance between the embodiment of the present invention and a comparative example.

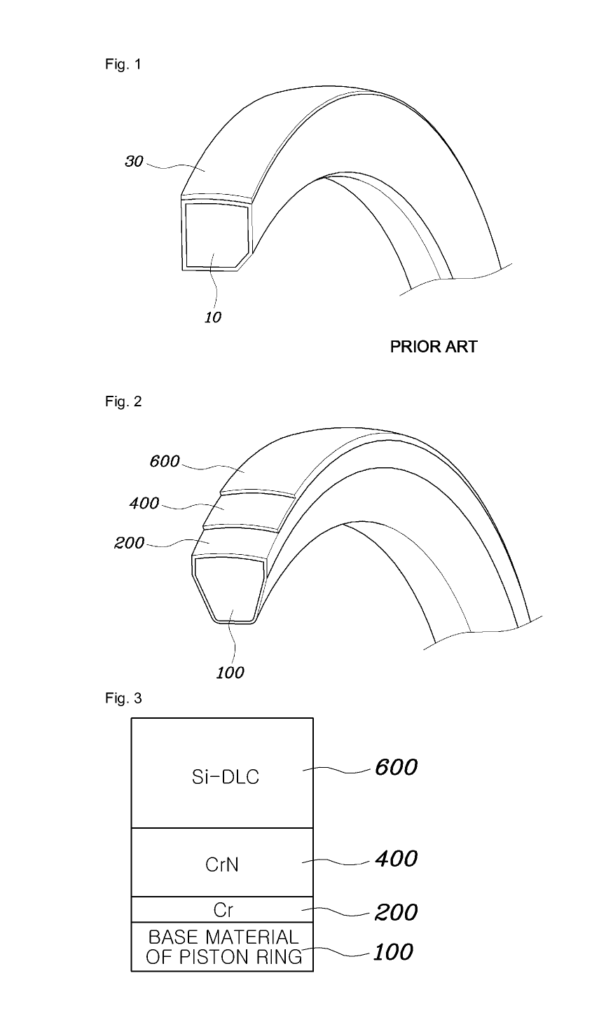

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that the present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

A piston ring for an engine and a manufacturing method thereof according to a preferred embodiment of the present invention will be described below with reference to the accompanying drawings.

FIG. 2 is a view showing a piston ring for an engine in accordance with an embodiment of the present invention, and FIG. 3 is a sectional view showing a coating of the piston ring for the engine shown in FIG. 2.

The piston ring for the engine according to the present invention includes a Cr coating layer 200 coated on a surface of a base material 100, and an Si-DLC (Diamond Like Carbon) coating layer 600 coated on an outermost layer of the base material 100 and comprising about 3 to 10 wt. % of Si. A CrN coating layer 400 may in some embodiments be further provided between the Cr coating layer 200 and the Si-DLC coating layer 600.

Such a configuration can reduce the friction loss of the piston ring and improve fuel efficiency by at least 0.2 to 0.5% because the frictional coefficient of Si-DLC is less than Cr plating and nitriding by at least 23%, and is less than CrN by at least 11%. Further, the scuffing resistance of the Si-DLC is superior to Cr plating and nitriding by at least 50%, and is superior to just CrN by at least 30% or more, thus suppressing the destruction of an oil film and improving the durability of the piston ring.

Further, Si is doped on DLC to enhance the low friction and high-temperature abrasion resistance characteristics of the DLC. Therefore, even if the Si-DLC is worn out, a multilayered structure composed of Cr and CrN forms a lower layer, and thus improves the durability of the piston ring.

In the exemplary embodiment of the present invention, the Si-DLC coating layer 600 may have the thickness of 0.1 to 10 μm. Further, Si may be uniformly distributed in the Si-DLC coating layer 600. The Si-DLC coating layer 600 may be formed such that Si content increases from an inner portion to an outer portion of the coating layer 600. When the Si content varies in stages/level or layers, the Si-DLC coating layer 600 can more effectively maintain low friction and high durability even at high temperatures.

In the illustrative embodiment of the present invention, the Si-DLC coating layer 600 is formed by chemical reaction between carbonization gas (CₓH_{y}) and TMS gas or between carbonization gas and HMDSO gas. However, any method of forming the Si-DLC layer 600 is acceptable. Further, it is desirable that the Cr coating layer 200 and the Si-DLC coating layer 600 be treated on only an outer circumference of the base material 100 which makes contact with an inner wall of a cylinder.

As such, the Si-DLC applied to the present invention is a coating material that has a lower frictional coefficient and higher hardness than CrN and thus is very effective for decreasing friction, abrasion resistance, and scuffing resistance of the piston ring. Further, since the Si-DLC is formed by uniformly or gradually doping Si, it can maintain low friction and high durability even at high temperatures unlike conventional DLC layering.

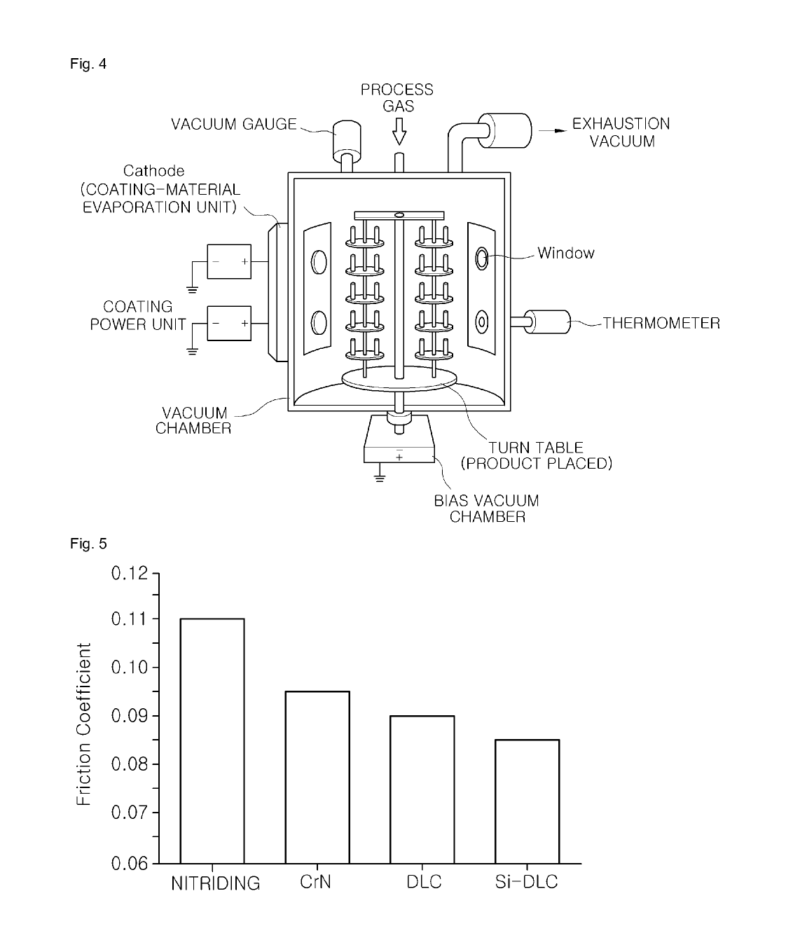

Meanwhile, FIG. 4 is a view showing an apparatus for manufacturing the piston ring for the engine shown in FIG. 2. A method of manufacturing the piston ring for the engine according to the present invention using this apparatus will be described below.

The method of manufacturing the piston ring for the engine according to the present invention includes coating the Cr coating layer 200 on the base material, and forming a Si-DLC coating layer 600 through a chemical reaction between carbonization gas (CₓH_{y}) and TMS gas, or between carbonization gas and HMDSO gas on top of the Cr layer 200.

Additionally, the illustrative embodiment of the present invention may also include forming a CrN coating layer 400 by the chemical reaction between N₂ gas and sputtered Cr ions between the Cr layer and the Si-DLC layer of the piston ring.

Further, the Si content may be increased from an inner portion to an outer portion of the Si-DLC coating layer 600 by controlling the injection quantity of TMS or HMDSO gas. The Si-DLC coating step may achieve 3 to 10 wt. % of Si in the resulting layer.

More specifically, the Si-DLC coating process of the present invention forms Cr (using a PVD, Physical Vapor Deposition method)+CrN (using a PVD method)+Si-DLC (using a PACVD, Plasma Assisted Chemical Vapor Deposition method) on the outer circumference of the piston ring in a multi-layered structure as shown in FIG. 3. The outermost Si-DLC layer is formed such that about 3 to 10 at. % of Si is uniformly distributed by monolithic coating or the Si content of the DLC is gradually increased from the inner portion containing about 3 wt. % to the outer portion containing about 10 at. % by graded coating.

As shown in FIG. 4, the piston ring of the present invention is coated by, e.g., vacuum coating equipment using a Cr target and a process gas comprising Argon (Ar), Nitrogen gas (N₂) and carbonization gas (CₓH_{y}), TMS or HMDSO gas.

First, in the exemplary method for manufacturing the above invention, a plasma state is obtained using Ar gas under a vacuum condition, a coating chamber is heated to 80° C. to activate a surface of the piston ring, and bias power is supplied to cause Ar ions to collide with the surface of the piston ring, thus cleaning the surface of the piston ring (baking & cleaning). Subsequently, in order to increase a close contact force between the coating layer and the base material, the Cr layer is coated using only the Cr target (thickness of 0.1 to 1.0 μm).

Further, the process gas N₂ is supplied to perform a chemical reaction with the sputtered Cr ions in the Cr target, thus coating the CrN layer (thickness of about 0.1 to 10 μm). Thereafter, if a chemical reaction is performed not using the Cr target but instead using the carbonization gas and TMS or HMDSO gas, C and Si are bonded together to form the Si-DLC layer (thickness of 0.1 to 10 μm).

Here, if gas (TMS or HMDSO) containing Si is supplied at a constant rate, the Si content of the DLC can maintain about 3 to 10 wt. %. Meanwhile, if a small quantity of gas containing Si is supplied in an initial stage and then the quantity of the gas is gradually increased, the Si content of the DLC may increase from about 3 at. % at the inner portion to about 10 wt. % at the outer portion.

FIGS. 5 to 7 are graphs showing the comparison of performance between the embodiment of the present invention and a comparative example. FIG. 5 illustrates the comparison of a frictional coefficient. A reciprocating friction-wear tester measures a frictional coefficient between the piston ring and a cylinder liner. The test is carried out under the condition of having a load of 150N, a temperature of 150° C., an oscillating period of 5 Hz, and oil. The test result is Si-DLC<DLC<CrN<nitriding as shown in FIG. 5. That is, the nitriding is the highest and the Si-DLC is the lowest in frictional coefficient. Further, as a doping process is performed while the Si content is changed, the frictional coefficient of the Si-DLC is further reduced.

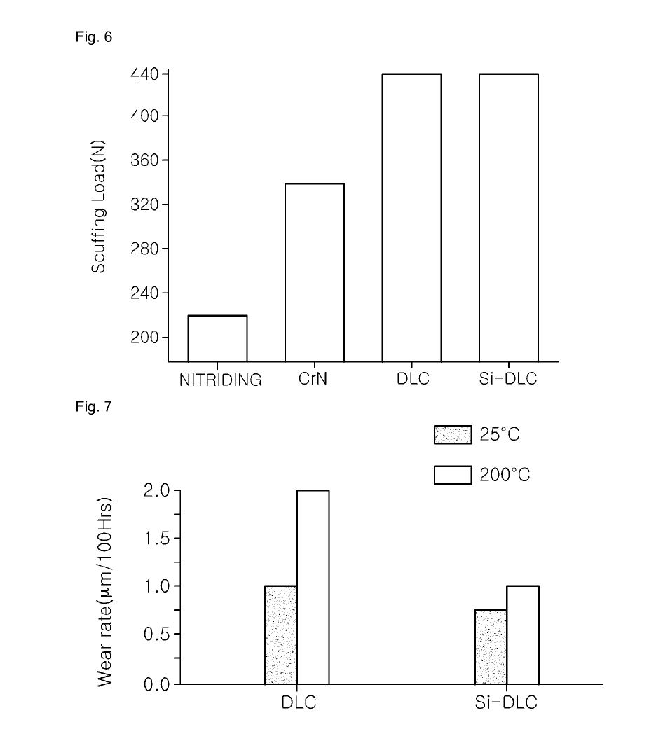

FIG. 6 illustrates the comparison of scuffing resistance. The reciprocating friction-wear tester measures a scuffing generating load between the piston ring and the cylinder liner to compare resistance to destruction of the oil film. The test is carried out under the condition that a load increases up to 440N by 20N at an interval of 20 minutes, a temperature is 150° C., an oscillating period is 5 Hz, and there exists oil. The test result is nitriding<CrN<DLC=Si-DLC as shown in FIG. 6. The nitriding generates the fastest scuffing, and the DLC and Si-DLC have the highest scuffing generating load.

FIG. 7 illustrates the comparison of high-temperature abrasion resistance. The reciprocating friction-wear tester measures an abrasion loss of the piston ring between the piston ring and the cylinder liner. The test is carried out for 1 hour under the condition of having a load of 150N, temperatures of 25° C. and 200° C., an oscillating period of 5 Hz, and oil. The test result is shown in FIG. 7. That is, the abrasion loss of DLC considerably increases at high temperatures, whereas the abrasion loss of Si-DLC does not considerably increase. Further, in the case of doping after adjusting the Si content, the abrasion resistance of the Si-DLC is further improved at high temperatures.

That is, the piston ring for the engine constructed as described above and the manufacturing method thereof achieves the following result: the frictional coefficient of Si-DLC is less than Cr plating and nitriding by at least 23%, and is less than CrN by at least 11%, thus reducing the friction loss of the piston ring and improving fuel efficiency by at least 0.2 to 0.5%.

Further, the scuffing resistance of the Si-DLC is superior to Cr plating and nitriding by at least 50%, and is superior to CrN by at least 30% or more, thus suppressing the destruction of the oil film and improving the durability of the piston ring. Furthermore, the Si is doped on the DLC, thus improving low friction and high-temperature abrasion resistance of the DLC. Meanwhile, even if the Si-DLC is worn out, the lower/inner layer comprises a multilayered structure having the Cr and CrN, thus improving the durability of the piston ring.

The present invention is advantageous in that the scuffing resistance of Si-DLC is superior to Cr plating and nitriding by at least 50%, and is superior to CrN by at least 30% or more, thus suppressing the destruction of an oil film and improving the durability of a piston ring. Further, the present invention is advantageous in that Si is doped on DLC, thus improving low friction and high-temperature abrasion resistance of the DLC. Furthermore, the present invention is advantageous in that, even if Si-DLC is worn out, a lower/inner layer has a multilayered structure having Cr and CrN, thus improving the durability of a piston ring.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A piston ring for an engine comprising:
a Cr (Chromium) coating layer coated on a surface of a base material; and
an Si-DLC (Silicon doped Diamond Like Carbon) coating layer coated on an outermost layer above the Cr coating layer and the base material, the Si-DLC layer include about 3 to 10 wt. % of Si.

2. The piston ring of claim 1, further comprising:
a CrN (Chromium Nitride) coating layer coated between the Cr coating layer and the Si-DLC coating layer.

3. The piston ring of claim 1, wherein the Si-DLC coating layer has a thickness of 0.1 to 10 μm.

4. The piston ring of claim 1, wherein the Si is uniformly distributed in the Si-DLC coating layer.

5. The piston ring of claim 1, wherein Si content of the Si-DLC coating layer is increased in a direction from an inner portion to an outer portion of the Si-DLC coating layer.

6. The piston ring of claim 1, wherein the Si-DLC coating layer is formed by chemical reaction between carbonization gas (CₓH_{y}) and TMS (Tetra-methylsilane, Si(CH₃)₄) gas.

7. The piston ring of claim 1, wherein the Si-DLC coating layer is formed by chemical reaction between or between carbonization gas and HMDSO (Hexamethyldisiloxane, O(Si(CH₃)₃)₂) gas.

8. The piston ring of claim 1, wherein the Cr coating layer and the Si-DLC coating layer are formed on only an outer circumference of the base material which makes contact with an inner wall of a cylinder.

9. A method of manufacturing a piston ring for an engine comprising:
a) coating a Cr coating layer on a base material of the piston ring; and
b) coating a Si-DLC coating layer through chemical reaction between carbonization gas (CₓH_{y}) and TMS gas or between carbonization gas and HMDSO gas on above the Cr coating layer on the piston ring.

10. The method of claim 8, further comprising:
coating a Chromium Nitride (CrN) coating layer through chemical reaction between N₂ gas and sputtered Cr ions, at a) to form the CrN coating layer between the Si-DLC coating layer and the Cr coating layer.

11. The method of claim 8, wherein, at b), an injection quantity of the TMS or the HMDSO gas is adjusted so that Si content of the Si-DLC coating layer is increased from an inner portion to an outer portion of the Si-DLC coating layer.

12. The method of claim 8, wherein, at b), the Si-DLC coating layer comprises about 3 to 10 wt. % of Si.
